(19) United States
(12) Patent Application Publication
(10) Pub. No.: US 2025/0320647 A1
(43) Pub. Date: Oct. 16, 2025

(54) Stretchable Electrically Conductive Fabrics And Methods For Improving Stretchability Of Electrical Conductive Fabrics

(71) Applicant: Laird Technologies (Shanghai) Co., Ltd., Shanghai City (CN)

(72) Inventors: Tsang-I TSAI, Xinbei City (TW); Dong-Xiang LI, Shenzhen (CN)

(21) Appl. No.: 19/248,116

(22) Filed: Jun. 24, 2025

Related U.S. Application Data
(63) Continuation of application No. PCT/CN2023/072199, filed on Jan. 13, 2023.

(30) Foreign Application Priority Data
Jan. 12, 2024 (CN) 202410051245.0
Jan. 12, 2024 (CN) 202420089560.8

(51) Int. Cl. D06C 15/08; D06B 1/02

(52) U.S. Cl. CPC D06C 15/08; D06B 1/02; D10B 2331/04; D10B 2401/16

(57) ABSTRACT

The present disclosure relates to stretchable electrically conductive fabrics and methods for improving stretchability of electrically conductive fabrics. In exemplary embodiments, a method includes providing an electrically conductive fabric with a pattern of openings extending at least partially or entirely through a thickness of the electrically conductive fabric. The openings are devoid of the electrically conductive fabric and operable for improving stretchability of the electrically conductive fabric. In exemplary embodiments, a stretchable electrically conductive fabric comprises a pattern of openings extending at least partially or entirely through a thickness of the stretchable electrically conductive fabric. The openings are devoid of the stretchable electrically conductive fabric and operable for improving stretchability of the stretchable electrically conductive fabric.

### CROSS-REFERENCE TO RELATED APPLICATIONS

This application is continuation of PCT International Patent Application No. PCT/CN2023/072199 filed Jan. 13, 2023, which published as WO2024/148625 on Jul. 18, 2024.

This application claims priority to and the benefit of (1) Chinese Invention patent application Ser. No. 20/241,0051245.0 filed Jan. 12, 2024, which published as CN 118345549 A on Jul. 16, 2024 and (2) Chinese Utility Model application Ser. No. 20/242,0089560.8 filed Jan. 12, 2024, which granted as Utility Model Patent No. ZL 202420089560.8 on Sep. 13, 2024.

The entire disclosures of each of the above applications are incorporated herein by reference.

### FIELD

The present disclosure relates to stretchable electrically conductive fabrics and methods for improving stretchability of electrically conductive fabrics.

### BACKGROUND

This section provides background information related to the present disclosure which is not necessarily prior art.

A common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source.

For example, an electrically conductive fabric may be used as an EMI shield. In this example, a fabric may be plated with metal to make the fabric electrically conductive. The metal plated fabric may then be used as an EMI mitigation material, electrical grounding material, etc. The metal plated fabric may also be required to be stretchable, e.g., for attachment within a housing of an electronic device, etc.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

### DRAWINGS

The drawings described herein are for illustrative purposes only of selected embodiments and not all possible implementations, and is not intended to limit the scope of the present disclosure.

FIG. 1 shows a conventional nickel/copper plated polyester taffeta fabric.

FIG. 2 shows a nickel/copper plated polyester taffeta fabric (broadly, a stretchable electrically conductive fabric) including a first pattern of cross shaped or + shaped openings extending at least partially or entirely through the thickness of the nickel/copper plated polyester taffeta fabric for improving stretchability according to an exemplary embodiment of the present disclosure.

FIG. 3 shows a nickel/copper plated polyester taffeta fabric (broadly, a stretchable electrically conductive fabric) including a second pattern of X shaped openings extending at least partially or entirely through the thicknesses of the nickel/copper plated polyester taffeta fabric for improving stretchability according to an exemplary embodiment of the present disclosure.

FIG. 4 shows a nickel/copper plated polyester taffeta fabric (broadly, a stretchable electrically conductive fabric) including a third pattern of square shaped or diamond shaped openings extending at least partially or entirely through the thicknesses of the nickel/copper plated polyester taffeta fabric for improving stretchability according to an exemplary embodiment of the present disclosure.

FIG. 5 shows five test samples of stretchable electrically conductive fabrics laminated to foams for elongation/tension testing, including a conventional nickel plated polyester knit fabric, the conventional nickel/copper plated polyester taffeta fabric shown in FIG. 1 and the nickel/copper plated polyester taffeta fabrics including the first, second, and third patterns of openings respectively shown in FIGS. 2, 3, and 4.

FIG. 6 shows an exemplary machine being used for stretching the fifth test sample laminated to foam as shown in FIG. 5 that included nickel/copper plated polyester taffeta fabric having the third pattern of square shaped or diamond shaped openings as shown in FIG. 4.

FIG. 7 shows the five test samples of electrically conductive fabrics laminated to foams previously shown unstretched in FIG. 5 after being stretched via the machine shown in FIG. 6.

FIG. 8 includes a table of example test results for the five test samples before stretching (FIG. 5) and after stretching (FIG. 7) including initial electrical resistance in Ohms before stretching, force in Newtons (N) at 10 percent elongation and deformation percentage after the test, force in Newtons (N) at 20 percent elongation and deformation percentage after the test, and electrical resistance in Ohms after stretching.

Corresponding reference numerals may indicate corresponding (though not necessarily identical) features throughout the several views of the drawings.

### DETAILED DESCRIPTION

Example embodiments will now be described more fully with reference to the accompanying drawings.

As noted above, a fabric may be plated with metal to make the fabric electrically conductive. The metal plated fabric may then be used as an EMI mitigation material or electrical grounding material. The metal plated fabric should also be stretchable.

A stretchable fabric may be metal plated via a traditional fabric metal plating process to make the fabric electrically conductive. But as recognized herein, the metal plating process may require costly electroplating equipment in order to electroplate metal onto the stretchable fabric for sufficient electrically conductivity while also attempting to maintain sufficient stretchability. But as also recognized herein, the metal plating on fabric will decrease the stretchability of the fabric. In which case, the metal plated fabric may behave like a plain weave electrically conductive fabric requiring very high tension forces for stretching the metal plated fabric. Accordingly, it can be a challenging endeavor to provide a stretchable electrically conductive fabric having good stretchability or elongation/tension performance while also having sufficiently good electrical conductivity before and after stretching.

After recognizing the above, exemplary embodiments of stretchable electrically conductive fabrics and methods for improving stretchability of electrically conductive fabrics were developed and/or are disclosed. In exemplary embodiments disclosed herein, the stretchable electrically conductive fabrics are provided with a pattern of openings (e.g., cuts, slits, etc.) that enable the electrically conductive fabrics to be stretched at lower tensile forces (e.g., FIG. 8, etc.) and/or that enable the electrically conducive fabrics to have better elongation/tension performance. The electrically conductive fabrics may also be configured to maintain good or sufficient electrical conductivity (e.g., FIG. 8, etc.) before and after the electrically conductive fabrics are stretched.

In exemplary embodiments, the stretchable electrically conductive fabric comprises a metal plated fabric that is cut or otherwise provided (e.g., via a rotary cutter, programmable knife cutter, etc.) with a pattern of openings (e.g., cuts, slits, etc.) that define deformation areas/spaces devoid of the metal plated fabric. The additional deformation space provided at the openings or cut areas enables the metal plated fabric to be stretched at lower tensile forces (e.g., FIG. 8, etc.). In exemplary embodiments, the metal plated fabric is configured to have an overall low tensile strength with high elongation, thin thickness, and high recovery. Cutting the pattern of openings (e.g., cuts, slits, etc.) that define deformation areas/spaces devoid of the metal plated fabric improves stretchability without requiring a very high cost and highly complicated process. As disclosed herein, the design of the cutting mold or tool and the distribution or spacing of the pattern of openings impacts the stretchability of the electrically conductive fabric.

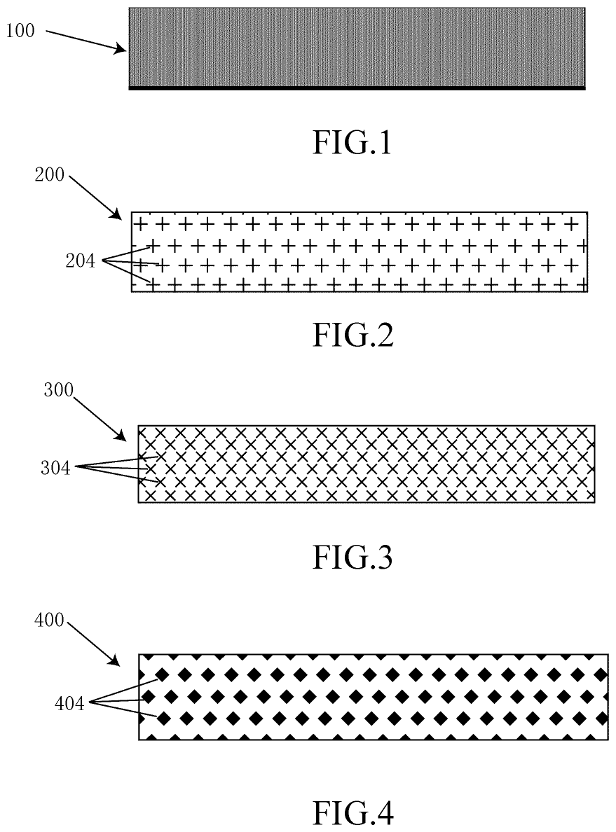

FIG. 1 shows a conventional nickel/copper plated polyester taffeta fabric 101 that does not include any pattern of openings cut into the fabric. The nickel/copper plated polyester taffeta fabric 101 may have the properties as shown in FIG. 8 for the Origin Fabric-Nickel/Copper Plated Polyester Taffeta Fabric with 0.08 mm initial thickness.

FIG. 2 shows a nickel/copper plated polyester taffeta fabric 200 (broadly, a stretchable electrically conductive fabric) including a first pattern of openings 204 extending at least partially or entirely through the thickness of the nickel/copper plated polyester taffeta fabric 200 for improving stretchability according to exemplary embodiments of the present disclosure. In this exemplary embodiment, the nickel/copper plated polyester taffeta fabric 200 includes cross shaped or + shaped openings 204. The pattern of cross shaped or + shaped openings 204 enable the nickel/copper plated polyester taffeta fabric 200 to be stretched at lower tensile forces (e.g., FIG. 8, etc.) and/or to have better elongation/tension performance. In alternative embodiments, the nickel/copper plated polyester taffeta fabric 200 may be provided with a pattern of one or more openings having a different configuration(s), e.g., X shaped openings, openings shaped as alphanumeric characters, openings shaped as geometric polygonal shapes, quadrilaterals, rhombuses, squares, triangles, circles, etc. The nickel/copper plated polyester taffeta fabric 200 may have the properties as shown in FIG. 8 for the Origin Fabric with Pattern 1 (Cross Shaped Openings).

FIG. 3 shows a nickel/copper plated polyester taffeta fabric 300 (broadly, a stretchable electrically conductive fabric) including a second pattern of openings 304 extending at least partially or entirely through the thicknesses of the nickel/copper plated polyester taffeta fabric 300 for improving stretchability according to exemplary embodiments of the present disclosure. In this exemplary embodiment, the nickel/copper plated polyester taffeta fabric 200 includes X shaped openings 304. The pattern of X shaped openings 304 enable the nickel/copper plated polyester taffeta fabric 300 to be stretched at lower tensile forces (e.g., FIG. 8, etc.) and/or to have better elongation/tension performance. In alternative embodiments, the nickel/copper plated polyester taffeta fabric 300 may be provided with a pattern of one or more openings having a different configuration(s), e.g., cross shaped openings, plus sign shaped openings, + shaped openings, openings shaped as alphanumeric characters, openings shaped as geometric polygonal shapes, quadrilaterals, rhombuses, squares, triangles, circles, etc. The nickel/copper plated polyester taffeta fabric 300 may have the properties as shown in FIG. 8 for the Origin Fabric with Pattern 2 (X Shaped Openings).

FIG. 4 shows nickel/copper plated polyester taffeta fabric 400 (broadly, a stretchable electrically conductive fabric) each including a third pattern of openings 404 extending at least partially or entirely through the thicknesses of the nickel/copper plated polyester taffeta fabrics 400 for improving stretchability according to exemplary embodiments of the present disclosure. In this exemplary embodiment, the nickel/copper plated polyester taffeta fabric 400 includes square shaped or diamond shaped openings 404. The pattern of square shaped or diamond shaped openings 404 enable the nickel/copper plated polyester taffeta fabric 400 to be stretched at lower tensile forces (e.g., FIG. 8, etc.) and/or to have better elongation/tension performance. In alternative embodiments, the nickel/copper plated polyester taffeta fabric 400 may be provided with a pattern of one or more openings having a different configuration(s), e.g., X shaped openings, cross shaped openings, plus sign shaped openings, + shaped openings, openings shaped as alphanumeric characters, openings shaped as geometric polygonal shapes, quadrilaterals, rhombuses, squares, triangles, circles, etc. The nickel/copper plated polyester taffeta fabric 300 may have the properties as shown in FIG. 8 for the Origin Fabric with Pattern 3 (Square Shaped Openings).

By way of example, the pattern of openings may be formed in an electrically conductive fabric by a cutting process without removing material. In one exemplary method, the openings are formed by feeding a metal plated fabric (e.g., nickel/copper plated polyester taffeta fabric, etc.) through a rotary die cutter. Alternative processes (e.g., programmable knife blade, etc.) may also be used to provide the pattern of openings in an electrically conductive fabric, depending, for example, on the penetration depth of the openings into the electrically conductive fabric (e.g., penetration depth greater than or lesser than seventy percent of the total thickness of the electrically conductive fabric, penetration depth of one hundred percent or entirely through the total thickness of the electrically conductive fabric, etc.). By way of example, some embodiments may include forming the pattern of openings in an electrically conductive fabric such that fabric material is removed, such as by notching out the pattern of openings in the electrically conductive fabric.

In exemplary embodiments, the stretchable electrically conductive fabric comprises a nickel/copper plated polyester taffeta fabric. The polyester taffeta fabric is plated or metallized with the highly conductive copper and corrosion resistant nickel. The nickel/copper plated polyester taffeta fabric is thereafter cut or otherwise provided (e.g., via a rotary cutter, programmable knife cutter, cutting in a machine direction, cutting in a 45 degree angle relative to the machine direction, etc.) with a pattern of openings that define deformation areas/spaces devoid of the nickel/copper polyester taffeta materials. By way of example, the dimensions of the footprint or surface area defined by each opening may be 3 millimeters (mm)×3 mm, 5 mm×5 mm, less than 3 mm×3 mm, more than 5 mm×5 mm, etc. Advantageously, the pattern of openings enable the electrically conductive fabric to be stretchable at lower tensile forces (e.g., FIG. 8, etc.) and/or to have better elongation/tension performance. The electrically conductive fabric may also be configured to maintain good or sufficient electrical conductivity (e.g., FIG. 8, etc.) before and after the electrically conductive fabrics are stretched. The stretchable electrically conductive fabric may also include one or more (but not necessarily any or all) of the following features: flexible, lightweight, corrosion resistant, highly conductive, excellent shielding performance, excellent electrical properties, fewer seams required, maximum operating temperature of 210° C., a shelf life of 12 months in a sealed bag under 0-40° C., thickness within a range from about 0.07 millimeters (mm) to about 0.09 mm (e.g., thickness of about 0.080 millimeters, etc.), and ROHS compliance. In other exemplary embodiments, the stretchable electrically conductive fabric may be configured differently, such as being made from other materials (e.g., other fabric substrates, plated with other metals, provided with other electrically conductive materials, etc.) and/or configured with other properties, etc.

For example, another exemplary embodiment includes a stretchable electrically conductive fabric comprising a nickel/copper plated polyester non-woven fabric that is cut or otherwise provided with a pattern of openings (e.g., cross shaped openings, X shaped openings, square or diamond shaped openings, etc.) that define deformation areas/spaces devoid of the nickel/copper plated polyester non-woven fabric. In an additional exemplary embodiment, the stretchable electrically conductive fabric comprises a nickel/copper plated polyester mesh fabric that is cut or otherwise provided with a pattern of openings (e.g., cross shaped openings, X shaped openings, square or diamond shaped openings, etc.) that define deformation areas/spaces devoid of the nickel/copper plated polyester mesh fabric. In a further exemplary embodiment, the stretchable electrically conductive fabric comprises a nickel/copper plated nylon ripstop (NRS) fabric that is cut or otherwise provided with a pattern of openings (e.g., cross shaped openings, X shaped openings, square or diamond shaped openings, etc.) that define deformation areas/spaces devoid of the nickel/copper plated nylon ripstop fabric.

In exemplary embodiments, the stretchable electrically conductive fabric comprises a metallized fabric that utilizes electrically conductive metals, such as nickel, gold, carbon, stainless steel, titanium, etc. The fabric substrate may comprise cotton, wool, polyester, nylon, etc. The fabric substrate may be made by various methods, such as by using elastic fibers, curly fibers, special knitting, etc. In exemplary embodiments, the stretchable fabric included a special knitting mesh having excellent stretching performance (e.g., FIG. 8, etc.) and that is also associated with a relatively lower cost. The stretchable electrically conductive fabric may be configured to have corrosion resistance and a NFPA Class A Flame rating. In exemplary embodiments, the stretchable electrically conductive fabric is configured to dissipate static energy and help mitigate unwanted electromagnetic interference. The stretchable electrically conductive fabric may also be configured to be thermally conductive and usable for thermal regulation. The stretchable electrically conductive fabric may be configured to be usable for managing of thermal and/or electromagnetic properties of a device or system. The stretchable electrically conductive fabric may be configured with other attributes, such as anti-allergy and anti-bacterial properties.

In exemplary embodiments, the conductive properties of the stretchable electrically conductive fabric may be used to facilitate the integration of a “soft network” into the fabric. In which case, the stretchable electrically conductive fabric may be referred to as a smart fabric or intelligent textile. The smart fabric is not passive in its function as the smart fabric may be configured to sense and respond to stimuli such as touch, temperature, or heartbeat. The smart fabric may be used as a “switch” in an electronic circuit to perform a function for another external electronic device wherein the switch happens when there is a connection between two electrically conductive fabrics.

In exemplary embodiments, the stretchable electrically conductive fabric is compliant with ROHS Directive 2011/65/EU and (EU) 2015/863 and/or compliant with REACH as containing less than 0.1% by weight of substances on the REACH/SVHC candidate list (Jun. 25, 2020). In exemplary embodiments, the stretchable electrically conductive fabric includes no more than a regulated threshold of 0.01% by weight of cadmium, no more than a regulated threshold of 0.1% by weight of Lead, no more than a regulated threshold of 0.1% by weight of mercury, no more than a regulated threshold of 0.1% by weight of hexavalent chromium, no more than a regulated threshold of 0.1% by weight of flame retardants PBB and PBDE including pentabromodiphenyl ether (CAS-No. 32534-81-9), octabromodiphenyl ether (CAS-No. 32536-52-0) and decabromodiphenyl ether (CAS-No. 1163-19-5), no more than a regulated threshold of 0.1% by weight of Bis(2-ethylhexyl) phthalate (DEHP) (CAS-No. 117-81-7), no more than a regulated threshold of 0.1% by weight of butyl benzyl phthalate (BBP) (CAS-No. 85-68-7), no more than a regulated threshold of 0.1% by weight of dibutyl phthalate (DBP) (CAS-No. 84-74-2), and no more than a regulated threshold of 0.1% by weight diisobutyl phthalate (DIBP) (CAS-No. 84-69-5).

A description will now be provided of an exemplary method for making a stretchable electrically conductive fabric having a pattern of openings (e.g., stretchable electrically conductive fabric 200 (FIG. 2), 300 (FIG. 3), 400 (FIG. 4), etc.). This example is provided for purposes of illustration only, as other methods, materials, and/or configurations may also be used.

This example method includes plating (e.g., electroplating, etc.) a polyester taffeta fabric (broadly, a fabric substrate) with copper (broadly, an electrically conductive plating). The method then includes plating (e.g., electroplating, etc.) the copper plated polyester taffeta fabric with nickel (broadly, a corrosion resistant plating). The method further includes feeding (e.g., via a conveyer or feeder mechanism, etc.) the nickel/copper plated polyester taffeta fabric through a rotary die cutter (broadly, a cutting mechanism) during which a pattern of openings (e.g., cross shaped openings, X shaped openings, square or diamond shaped openings, etc.) are cut into the nickel/copper plated polyester taffeta fabric. The pattern of openings are formed such that the nickel/copper plated polyester taffeta fabric is stretchable at lower tensile forces (e.g., FIG. 8, etc.) and has better elongation/tension performance. The pattern of openings may comprise cuts, slits, t-shaped openings, x-shaped openings, cross-shaped openings, plus signs, a repeating pattern of identical or similarly shaped openings, pattern of openings defining a scaley texture, alphanumeric characters, geometric polygonal shapes, quadrilaterals, rhombuses, squares, triangles, circles, etc.

The pattern of openings may be cut into the nickel/copper plated polyester taffeta fabric (or other electrically conductive fabric) such that at least one or more of the openings (e.g., all openings, less than all openings) penetrate and extend completely through the thicknesses of the nickel plating, the copper plating, and the polyester taffeta fabric. Alternatively, the pattern of openings may be cut into the nickel/copper plated polyester taffeta fabric such that at least one or more of the openings (e.g., all openings, less than all openings) do not penetrate and extend completely through the thicknesses of the nickel plating, the copper plating, and the polyester taffeta fabric. In which case, one or more of the openings may penetrate and extend completely through the thicknesses of the nickel plating and the copper plating but only partially through or not at all through the thickness of the polyester taffeta fabric.

The method may further including winding, reeling, or spooling the nickel/copper plated polyester taffeta fabric having the pattern of openings onto a reel or spool. The nickel/copper plated polyester taffeta fabric having the pattern of openings may be stored and/or shipped while it is on the reel or spool.

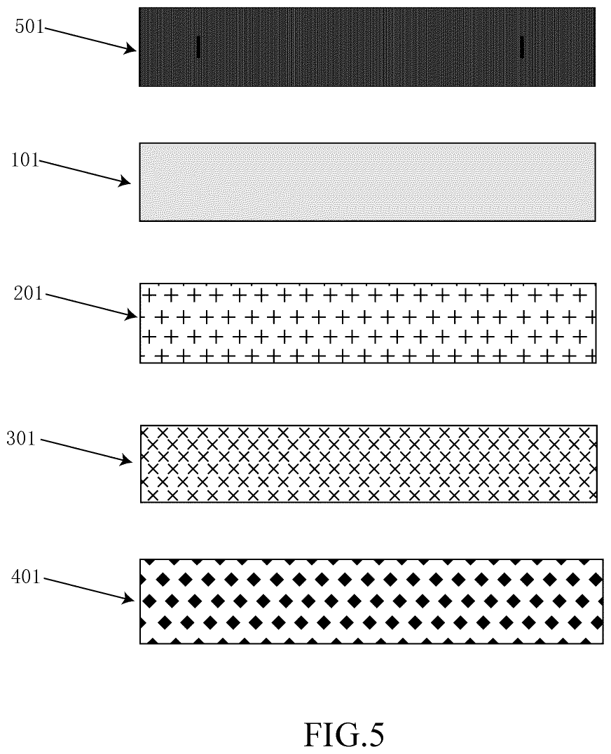

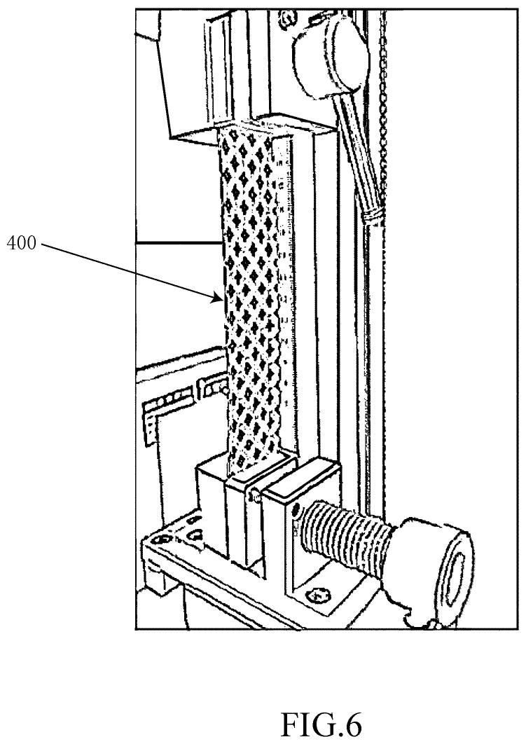

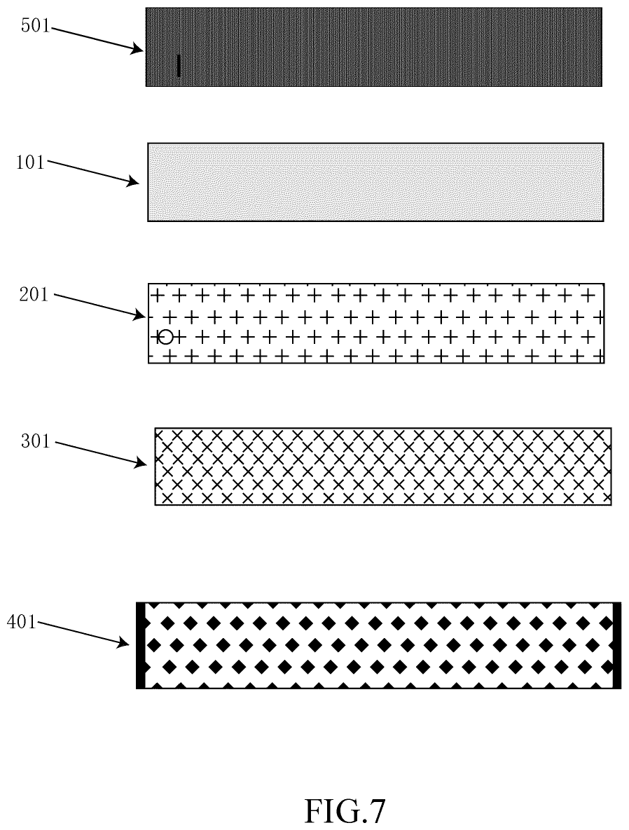

Exemplary testing was performed to determine whether providing (e.g., cutting, etc.) patterns of openings in nickel/copper plated polyester taffeta fabrics (broadly, stretchable electrically conductive fabrics) improved stretchability and enabled stretching at lower tensile forces and better elongation/tension performance. To this end, FIG. 8 includes a table of example test results for five test samples 501, 101, 201, 301, 401 shown before stretching in FIG. 5 and after stretching in FIG. 7. The five test samples 501, 101, 201, 301, 401 included differently configured electrically conductive fabrics that were laminated to foams for reinforcement during the elongation/tension testing, e.g., as fabrics with the openings cut therein may be too easily deformable and/or may be void and damaged during the testing, etc.

The first test sample 501 included nickel plated polyester knit fabric having an initial thickness of 0.30 mm. The first test sample 501 did not include any pattern of opening cut therein. As shown in FIG. 8, the first test sample 101 had an initial electrical resistance of 0.995 ohms before stretching, 3.21 force in Newtons (N) at 10 percent elongation with 0.52 deformation percentage afterwards, 6.653 force in Newtons (N) at 20 percent elongation with 0.80 deformation percentage afterwards, and electrical resistance of 1.226 ohms after stretching.

The second test sample 101 included nickel/copper plated polyester taffeta fabric having an initial thickness of 0.08 mm. The second test sample 101 did not include any pattern of openings cut therein. As shown in FIG. 8, the second test sample 101 had an initial electrical resistance of 0.028 before stretching, 78.0 force in Newtons (N) and 130.0 force in Newtons (N) at 20 percent elongation.

The third test sample 200 included the same origin fabric as the second test sample 101, i.e., nickel/copper plated polyester taffeta fabric having an initial thickness of 0.08 mm. But the third test sample 200 included the first pattern of cross shaped or + shaped openings 204 as shown in FIG. 2. As shown in FIG. 8, the third test sample 200 had an initial electrical resistance of 0.064 ohms before stretching, 9.2 force in Newtons (N) at 10 percent elongation with 1.50 deformation percentage afterwards, 20.26 force in Newtons (N) at 20 percent elongation with 3.95 deformation percentage afterwards, and electrical resistance of 0.064 ohms after stretching. Notably, the electrically conductive fabric 200 with the pattern of cross shaped or + shaped openings 204 had a lower electrical resistance than the first test sample 501 and a better elongation/tension performance than the second test sample 101.

The fourth test sample 300 included the same origin fabric as the second test sample 101, i.e., nickel/copper plated polyester taffeta fabric having an initial thickness of 0.08 mm. But the fourth test sample 300 included the second pattern of X shaped openings 304 as shown in FIG. 3. As shown in FIG. 8, the fourth test sample 300 had an initial electrical resistance of 0.048 ohms before stretching, 8.18 force in Newtons (N) at 10 percent elongation with 1.50 deformation percentage afterwards, 8.64 force in Newtons (N) at 20 percent elongation with 2.50 deformation percentage afterwards, and electrical resistance of 0.061 ohms after stretching. Notably, the electrically conductive fabric 300 with the pattern of X shaped openings 304 had a lower electrical resistance than the first test sample 501 and a better elongation/tension performance than the second test sample 101.

The fifth test sample 400 included the same origin fabric as the second test sample 101, i.e., nickel/copper plated polyester taffeta fabric having an initial thickness of 0.08 mm. But the fifth test sample 400 included the third pattern of square shaped or diamond shaped openings 404 as shown in FIG. 4. As shown in FIG. 8, the fifth test sample 400 had an initial electrical resistance of 0.059 ohms before stretching, 6.27 force in Newtons (N) at 10 percent elongation with 1.18 deformation percentage afterwards, 8.91 force in Newtons (N) at 20 percent elongation with 1.94 deformation percentage afterwards, and electrical resistance of 0.087 ohms after stretching. Notably, the electrically conductive fabric 400 with the pattern of square shaped or diamond openings 404 had a lower electrical resistance than the first test sample 501 and a better elongation/tension performance than the second test sample 101.

From this exemplary testing, it was observed that the first, second, and third pattern of openings improved stretchability and elongation/tension performance as compared to the conventional nickel/copper plated polyester taffeta fabric without any pattern of openings. It was also observed that that the nickel/copper plated polyester taffeta fabric 400 including the third pattern of square shaped or diamond shaped 404 shown in FIG. 4 required the lowest tensile forces of 6.27 N and 8.91 at 10% and 20% elongation, respectively.

Disclosed are exemplary methods for improving stretchability of electrically conductive fabrics, e.g., to enable the electrically conductive fabrics to be stretchable at lower tensile forces and/or to have better elongation/tension performance, etc. In exemplary embodiments, a method includes providing an electrically conductive fabric with a pattern of openings extending at least partially or entirely through a thickness of the electrically conductive fabric. The openings are devoid of the electrically conductive fabric and operable for improving stretchability of the electrically conductive fabric.

In exemplary embodiments, providing the electrically conductive fabric with the pattern of openings comprises cutting the openings into electrically conductive fabric. Cutting the openings into electrically conductive fabric may comprise using a rotary die cutter.

In exemplary embodiments, the electric conductive fabric comprises: a metal plated fabric including a fabric substrate and one or more metal platings; and providing the electrically conductive fabric with the pattern of openings comprises cutting the pattern of openings into the metal plated fabric.

In exemplary embodiments, the fabric substrate comprises a polyester taffeta fabric, a polyester non-woven fabric, a polyester mesh fabric, or a nylon ripstop (NRS) fabric; and/or the one or more metal platings comprise copper and nickel. The method may include: electrolessly depositing a copper plating on the fabric substrate; electrolessly depositing a nickel plating on the copper plating; and cutting the pattern of openings into the metal plated fabric such that the openings penetrate and extend completely through thicknesses of the nickel plating, the copper plating, and the fabric substrate. The method may also include feeding the metal plated fabric through a rotary die cutter during which the pattern of openings are cut into the metal plated fabric.

In exemplary embodiments, providing the electrically conductive fabric with the pattern of openings comprises providing the electrically conductive fabric with a repeating pattern of openings having a same shape.

In exemplary embodiments, providing the electrically conductive fabric with the pattern of openings comprises providing the electrically conductive fabric with a pattern of cross shaped openings, X shaped openings, square shaped openings, or diamond shaped openings.

In exemplary embodiments, the pattern of openings comprises: at least one opening having closed end portions that do not extend through opposing side edges of the electrically conductive fabric; and at least one other opening having at least one open end portion that extends through at least one of the opposing side edges of the electrically conductive fabric.

In exemplary embodiments, the pattern of openings are configured to enable the electrically conductive fabric to be stretched at lower tensile forces.

In exemplary embodiments, providing the electrically conductive fabric with the pattern of openings comprises: cutting the pattern of openings along the electrically conductive fabric in a machine direction or a longitudinal direction of the electrically conductive fabric; or cutting the pattern of opening along the electrically conductive fabric at about a forty-five degree angle relative to a machine direction or a longitudinal direction of the electrically conductive fabric.

In exemplary embodiments, the electric conductive fabric comprises a polyester taffeta fabric substrate, a copper plating on the fabric substrate, and a nickel plating on the copper plating. The method includes cutting the pattern of openings in the electrically conductive fabric that penetrate and extend completely through thicknesses of the nickel plating, the copper plating, and the polyester fabric substrate. The pattern of openings comprises a pattern of cross shaped openings, X shaped openings, square shaped openings, or diamond shaped openings.

In exemplary embodiments, the method includes using the electrically conductive fabric composite for managing thermal and/or electromagnetic properties of a device or system.

Also disclosed are exemplary embodiments of stretchable electrically conductive fabrics. In exemplary embodiments, the stretchable electrically conductive fabric comprises a pattern of openings extending at least partially or entirely through a thickness of the stretchable electrically conductive fabric. The openings are devoid of the stretchable electrically conductive fabric and operable for improving stretchability of the stretchable electrically conductive fabric.

In exemplary embodiments, the pattern of openings comprises a pattern of cuts into the stretchable electrically conductive fabric.

In exemplary embodiments, the stretchable electric conductive fabric comprises a metal plated fabric including a fabric substrate, one or more metal platings on the fabric substrate, and the pattern of openings cut into the metal plated fabric.

In exemplary embodiments, the fabric substrate comprises a polyester taffeta fabric, a polyester non-woven fabric, a polyester mesh fabric, or a nylon ripstop (NRS) fabric; and/or the one or more metal platings comprise copper and nickel. The one or more metal platings may comprise a copper plating on the fabric substrate, and a nickel plating on the copper plating. The openings may penetrate and extend completely through thicknesses of the nickel plating, the copper plating, and the fabric substrate.

In exemplary embodiments, the pattern of openings comprises a pattern of cross shaped openings, X shaped openings, square shaped openings, or diamond shaped openings.

In exemplary embodiments, the pattern of openings comprises: at least one opening having closed end portions that do not extend through opposing side edges of the stretchable electrically conductive fabric; and at least one other opening having at least one open end portion that extends through at least one of the opposing side edges of the stretchable electrically conductive fabric.

In exemplary embodiments, the pattern of openings enable the stretchable electrically conductive fabric to be stretched at lower tensile forces.

In exemplary embodiments, the pattern of openings comprises a plurality of cuts along the stretchable electrically conductive fabric in a machine direction or a longitudinal direction of the stretchable electrically conductive fabric. Or the pattern of openings comprises a plurality of cuts along the stretchable electrically conductive fabric at about a forty-five degree angle relative to a machine direction or a longitudinal direction of the stretchable electrically conductive fabric.

In exemplary embodiments, the stretchable electric conductive fabric comprises a polyester taffeta fabric substrate, a copper plating on the fabric substrate, and a nickel plating on the copper plating. The openings penetrate and extend completely through thicknesses of the nickel plating, the copper plating, and the polyester fabric substrate. And the pattern of openings comprises a pattern of cross shaped openings, X shaped openings, square shaped openings, or diamond shaped openings.

In exemplary embodiments, the stretchable electrically conductive fabric is an electromagnetic interference (EMI) mitigation material usable for managing electromagnetic properties of a device or system.

In exemplary embodiments, a device or system comprises stretchable electrically conductive fabric as disclosed herein that is used for managing thermal and/or electromagnetic properties of a device or system.

Exemplary embodiments of the stretchable electrically conductive fabrics disclosed herein may be used in a wide range of industries (e.g., telecom, medical, wearable electronics, etc.) and wide range of applications and products (e.g., medical equipment, wearable medical devices, notebook computers, plasma display panels, printers, telecommunications enclosure cabinets, etc.). In exemplary embodiments in which the stretchable electrically conductive fabric comprises a smart fabric or intelligent textile, the stretchable electrically conductive fabric may incorporate antennas, global positioning systems (GPS), mobile phones, and flexible display panels, without compromising the inherent characteristics of the stretchable electrically conductive fabric. Accordingly, aspects of the present disclosure should not be limited to use with any single type of electronic device, product, application, or industry.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. For example, when permissive phrases, such as “may comprise”, “may include”, and the like, are used herein, at least one embodiment comprises or includes the feature(s). As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about”, equivalents to the quantities are included.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for improving stretchability of an electrically conductive fabric, the method comprising providing an electrically conductive fabric with a pattern of openings extending at least partially or entirely through a thickness of the electrically conductive fabric, whereby the openings are devoid of the electrically conductive fabric and operable for improving stretchability of the electrically conductive fabric, wherein the pattern of openings comprises:
at least one opening having closed end portions that do not extend through opposing side edges of the electrically conductive fabric; and
at least one other opening having at least one open end portion that extends through at least one of the opposing side edges of the electrically conductive fabric.

2. The method of claim 1, wherein providing the electrically conductive fabric with the pattern of openings comprises cutting the openings into electrically conductive fabric.

3. The method of claim 2, wherein cutting the openings into electrically conductive fabric comprises using a rotary die cutter.

4. The method of claim 1, wherein:
the electric conductive fabric comprises a metal plated fabric including a fabric substrate and one or more metal platings; and
providing the electrically conductive fabric with the pattern of openings comprises cutting the pattern of openings into the metal plated fabric.

5. The method of claim 4, wherein:
the fabric substrate comprises a polyester taffeta fabric, a polyester non-woven fabric, a polyester mesh fabric, or a nylon ripstop (NRS) fabric; and/or
the one or more metal platings comprise copper and nickel.

6. The method of claim 4, wherein the method includes:
electrolessly depositing a copper plating on the fabric substrate;
electrolessly depositing a nickel plating on the copper plating; and
cutting the pattern of openings into the metal plated fabric such that the openings penetrate and extend completely through thicknesses of the nickel plating, the copper plating, and the fabric substrate.

7. The method of claim 4, wherein the method includes feeding the metal plated fabric through a rotary die cutter during which the pattern of openings are cut into the metal plated fabric.

8. The method of claim 1, wherein providing the electrically conductive fabric with the pattern of openings comprises:
providing the electrically conductive fabric with a repeating pattern of openings having a same shape; and/or
providing the electrically conductive fabric with the pattern of openings comprises providing the electrically conductive fabric with a pattern of cross shaped openings, X shaped openings, square shaped openings, or diamond shaped openings.

9. The method of claim 1, wherein providing the electrically conductive fabric with the pattern of openings comprises:
cutting the pattern of openings along the electrically conductive fabric in a machine direction or a longitudinal direction of the electrically conductive fabric; or
cutting the pattern of opening along the electrically conductive fabric at a forty-five degree angle relative to a machine direction or a longitudinal direction of the electrically conductive fabric.

10. The method of claim 1, wherein:
the electric conductive fabric comprises a polyester taffeta fabric substrate, a copper plating on the fabric substrate, and a nickel plating on the copper plating; and
the method includes cutting the pattern of openings in the electrically conductive fabric that penetrate and extend completely through thicknesses of the nickel plating, the copper plating, and the polyester taffeta fabric substrate; and
the pattern of openings comprises a pattern of cross shaped openings, X shaped openings, square shaped openings, or diamond shaped openings.

11. The method of claim 1, wherein:
the pattern of openings is configured to enable the electrically conductive fabric to be stretched at lower tensile forces; and/or
the method includes using the electrically conductive fabric for managing thermal and/or electromagnetic properties of an electronic device.

12. A stretchable electrically conductive fabric comprising a pattern of openings extending
at least partially or entirely through a thickness of the stretchable electrically conductive fabric, whereby the openings are devoid of the stretchable electrically conductive fabric and operable for improving stretchability of the stretchable electrically conductive fabric, wherein the pattern of openings comprises:
at least one opening having closed end portions that do not extend through opposing side edges of the stretchable electrically conductive fabric; and
at least one other opening having at least one open end portion that extends through at least one of the opposing side edges of the stretchable electrically conductive fabric.

13. The stretchable electrically conductive fabric of claim 12, the pattern of openings comprises a pattern of cuts into the stretchable electrically conductive fabric.

14. The stretchable electrically conductive fabric of claim 12, wherein the stretchable electric conductive fabric comprises a metal plated fabric including a fabric substrate, one or more metal platings on the fabric substrate, and the pattern of openings cut into the metal plated fabric.

15. The stretchable electrically conductive fabric of claim 14, wherein:
the fabric substrate comprises a polyester taffeta fabric, a polyester non-woven fabric, a polyester mesh fabric, or a nylon ripstop (NRS) fabric; and/or
the one or more metal platings comprise copper and nickel.

16. The stretchable electrically conductive fabric of claim 14, wherein:
the one or more metal platings comprise a copper plating on the fabric substrate, and a nickel plating on the copper plating; and
the openings penetrate and extend completely through thicknesses of the nickel plating, the copper plating, and the fabric substrate.

17. The stretchable electrically conductive fabric of claim 14, wherein:
the pattern of openings comprises a repeating pattern of openings having a same shape; and/or the pattern of openings comprises a pattern of cross shaped openings, X shaped openings, square shaped openings, or diamond shaped openings.

18. The stretchable electrically conductive fabric of claim 12, wherein the pattern of openings comprises:
a plurality of cuts along the stretchable electrically conductive fabric in a machine direction or a longitudinal direction of the stretchable electrically conductive fabric; or a plurality of cuts along the stretchable electrically conductive fabric at a forty-five degree angle relative to a machine direction or a longitudinal direction of the stretchable electrically conductive fabric.

19. The stretchable electrically conductive fabric of claim 12, wherein:
the stretchable electric conductive fabric comprises a polyester taffeta fabric substrate, a copper plating on the polyester taffeta fabric substrate, and a nickel plating on the copper plating;
the openings penetrate and extend completely through thicknesses of the nickel plating, the copper plating, and the polyester taffeta fabric substrate; and
the pattern of openings comprises a pattern of cross shaped openings, X shaped openings, square shaped openings, or diamond shaped openings.

20. The stretchable electrically conductive fabric of claim 12, wherein:
the stretchable electrically conductive fabric is an electromagnetic interference (EMI) mitigation material usable for managing electromagnetic properties of an electronic device; and/or
the pattern of openings enable the stretchable electrically conductive fabric to be stretched at lower tensile forces.
